(19) United States
(12) Patent Application Publication
(10) Pub. No.: US 2026/0078521 A1
(43) Pub. Date: Mar. 19, 2026

(54) METHOD FOR MANUFACTURING A PART WITH A DARK BLACK SURFACE

(71) Applicant: The Swatch Group Research and Development Ltd, Marin (CH)

(72) Inventors: Steve CLERC, Neuchâtel (CH); Stewes BOURBAN, Chabrey (CH)

(73) Assignee: The Swatch Group Research and Development Ltd, Marin (CH)

(21) Appl. No.: 19/302,287

(22) Filed: Aug. 18, 2025

(30) Foreign Application Priority Data
Sep. 18, 2024 (EP) 24200981.9

(51) Int. Cl. C30B 11/00; C30B 29/02; C30B 33/10

(52) U.S. Cl. CPC C30B 11/003; C30B 11/006; C30B 29/02; C30B 33/10

(57) ABSTRACT

A method for manufacturing a black structure of a material (10) including at least two phases, with at least one crystalline phase (1) and at least one other phase, referred to as the matrix (2). The steps include growing the material in a main direction (Z) so that the at least one crystalline phase forms a plurality of rods aligned with each other and the matrix extends between the rods; and removing at least part of the matrix between the rods of the at least one crystalline phase, so as to form a comb-type material structure with rods and light entrapment cavities between said rods.

### CROSS REFERENCE TO RELATED APPLICATIONS

This application claims priority to European Patent Application No. 24200981.9 filed Sep. 18, 2024, the entire contents of which are incorporated herein by reference.

### TECHNICAL FIELD OF THE INVENTION

The present invention relates to a method for manufacturing a part with the aim of producing a dark/intense/jet black surface. It also relates to the use of a black structure produced by the method according to any of the preceding claims for external horology parts.

The part, made for example of metal, ceramic or polymer, comprises at least two phases: at least one crystalline phase and another phase referred to as the matrix, the part being produced according to the following steps:
a growth method directed and/or oriented in a main direction of the at least two phases such that the at least one crystalline phase forms a plurality of rods rising or protruding, in particular from a carrier, said rods being substantially aligned with each other, the other phase, referred to as the matrix phase, extending between said rods;
a step in which the matrix between the rods is at least partially removed, so as to form a comb-like structure or a forest of rods or a multitude of rods.

### TECHNOLOGICAL BACKGROUND

To obtain intense black surfaces, a common method comprises a first step in which an aluminium surface is cleaned, followed by a second step in which carbon nanotubes are grown. In particular, the method involves chemical vapour deposition (CVD) of carbon nanotubes or microscopic carbon filaments in a vertical direction so as to produce a “forest” of carbon nanotubes. In particular, nanotubes are grown on the surface of an aluminium sheet etched with chlorine, in particular sodium chloride NaCl. This deposit absorbs light.

### SUMMARY OF THE INVENTION

To this end, and according to a first aspect, the invention provides a method for manufacturing a black structure or part of a material comprising at least two phases, with at least one crystalline phase and at least one other phase, referred to as the matrix, the method comprising the following steps:
growing the material in a main direction so that the at least one crystalline phase forms a plurality of rods aligned with each other and the matrix extends between said rods,
removing at least part of the matrix between said rods of the at least one crystalline phase, so as to form a comb-type material structure with rods and light entrapment cavities between said rods, so as to absorb light.

For the purposes of the foregoing and for the remainder of the description, the term “carrier” refers to a material which may or may not be the material intended to be directed and/or grown, and/or a material that has thermal and chemical properties allowing for directed solidification. The carrier material can be different according to the type of material directed; the carrier can have different geometries, such as a flat or three-dimensional face. The carrier can also be referred to as the starting face.

Preferably, the above steps in the method are carried out in this order.

According to different embodiments or variants which may or may not be combinable, the manufacturing method comprises or has the following characteristics or steps:
the material can be metal, ceramic, polymer or a combination thereof;
the material can be an alloy, preferably aluminium-based and/or nickel-based and/or zinc-based, for example a eutectic alloy;
the material can comprise carbon or graphite;
the at least one crystalline phase can comprise multiple crystalline phases;
the matrix can be or comprise one or more crystalline phases and/or one or more amorphous phases referred to as matrix phases;
the growth step corresponds to erecting or causing the material in question to protrude in a main direction, such that the rods are directed in said main direction, plus or minus 20 degrees, preferably plus or minus 10 degrees, preferably plus or minus 5 degrees;
the growth step can be carried out from a carrier, also known as the starting face;
the growth step can be carried out in a main direction substantially perpendicular to the starting face or carrier, in other words having an angle of 90 degrees relative to the starting face; preferably the growth direction has an angle comprised between 70 and 110 degrees;
the growth step is carried out by directional solidification, preferably thermal or by heating or cooling; in particular the directional solidification can be controlled by the cooling speed; for example, the directional solidification can be controlled at the exit of a furnace, for example by controlling the speed at the furnace exit and therefore the cooling;
preferably, the term “rod” refers to the at least one crystalline phase, filament, tube, blade, cylinder, dendrite, or any element that is arranged and can be configured to extend in a main longitudinal direction and extending to a lesser extent in a transverse direction, for example having transverse protrusions;
the starting face is preferably a solid phase arranged and configured to allow for directed growth, particularly in a perpendicular direction;
for example, the space between the rods can have a larger dimension than the diameter of the rods, the rod diameter can be at least 100 nanometres, the rod height can be at least 10 micrometres;
the growth step can, according to certain embodiments, provide about 5 to 20% of rods extending in a direction other than the main direction, for example forming an angle greater than 20 degrees relative to the main direction, preferably forming an angle greater than 30 degrees relative to the main direction, preferably forming an angle greater than 40 degrees relative to the main direction, preferably forming an angle greater than 50 degrees relative to the main direction;
the step in which least part of the matrix is removed is carried out without removing said rods or the at least one crystalline phase; nevertheless, the removal step can remove a percentage of the rods of the at least one crystalline phase, in particular less than 10%, preferably less than 5%;
the step in which at least part of the matrix is removed is a selective removal step set up and configured to act primarily on the matrix;
the removal step can be carried out chemically or electrochemically, thermally or physically, or by a combination of several of these methods;
the removal step can be set up and configured to limit or remove or dissolve at least partially protrusions extending transversely to the main direction of growth;
preferably, the space between the rods, corresponding to the at least other phase, is the site in which the surface or the volume or the medium is treated so as to dissolve or remove or limit at least part of the other phase;
the removal step can be carried out using a solution comprising NaOH or HNO3, preferably in a bath of said solution;
preferably, the manufacturing method can further comprise a blanking step in a direction that is transverse, or perpendicular, or orthogonal, plus or minus a few angular degrees, to the rod extension direction, particularly in the main direction, preferably between the growth step and the removal step;
preferably, the manufacturing method can further comprise a polishing, and/or sandblasting step.

According to one embodiment, the material comprises carbon nanotubes.

According to another embodiment, the material excludes carbon nanotubes.

According to another aspect, the invention provides an external horology part that can be produced using this method.

According to another aspect, the invention provides for the use of a black structure produced by this method for external horology parts.

According to another aspect, the invention provides a black part, in particular an external horology part, featuring a material comprising at least two phases, at least one of which is crystalline, and at least one other phase, referred to as the matrix, the part being produced using one or more of the characteristics or steps in the method for manufacturing the first aspect.

For example, this results in a metallurgical structure with a two-phase material.

### BRIEF DESCRIPTION OF THE FIGURES

Other features and advantages of the invention will be apparent from the following detailed description of the invention, with reference to the attached figures, in which:

FIG. 1 shows three schematic diagrams corresponding to three embodiments of a material erected from a starting face, each diagram showing rods aligned with each other in a main direction of at least one crystalline phase and at least one other phase disposed between the rods, each diagram having a schematic top view and a schematic side view;

FIG. 2 is a side view of a material with rods aligned with each other in a main direction of at least one crystalline phase and at least one other phase, known as the matrix, disposed between the rods, at least part of the matrix being removed between the rods according to one embodiment;

FIG. 3 is an electron microscope image of a material, seen from the side, with rods aligned with each other in a main direction of at least one crystalline phase according to one embodiment, and

FIG. 4 is an electron microscope image of a material, seen from above, in accordance with the previous figure.

For greater clarity, identical or similar elements in the different embodiments are labelled with identical reference numbers in all figures.

### DETAILED DESCRIPTION OF THE INVENTION

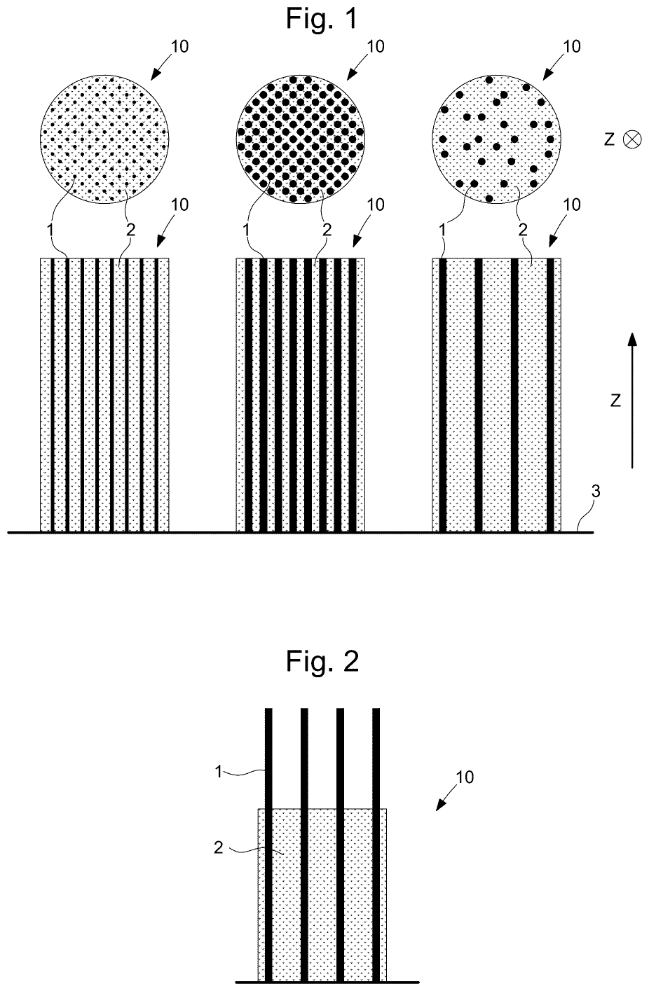

With reference to FIGS. 1 and 2, a method is described for manufacturing a part, in particular an external horology part, or a black structure made of a material 10 comprising two phases: a crystalline phase 1 and another phase, referred to as a matrix 2. Such an external part can correspond, in a non-limiting and non-exhaustive manner, to a bezel, a middle, a back, a casing ring, a retaining ring, a dial, a crown or even a hand.

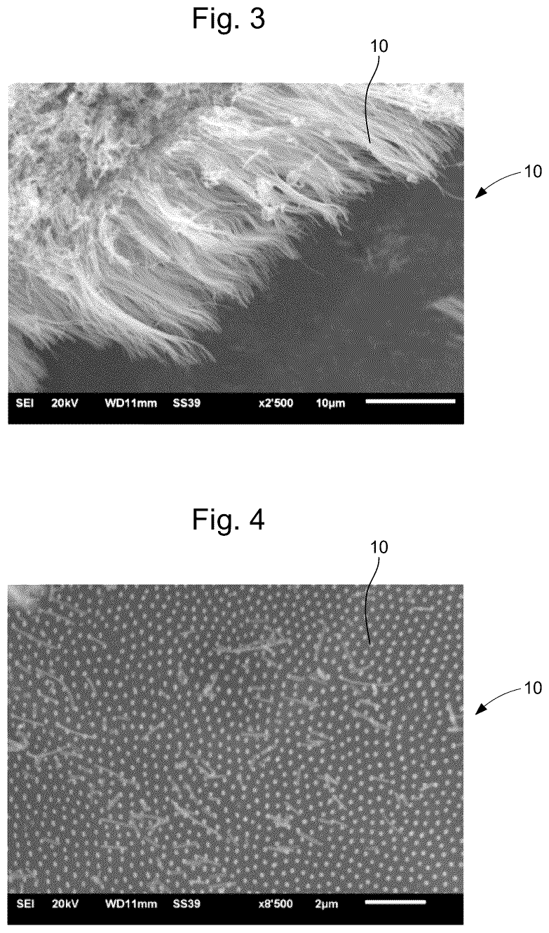

The method comprises the following steps in this order:
with reference to FIGS. 1 and 3, the material is grown according to a directional solidification method in a main direction Z from a starting face 3 such that the crystalline phase 1 forms a plurality of rods aligned with each other and the matrix 2 extends between the rods,
with reference to FIG. 2, at least part of the matrix between the crystalline phase rods is removed, to a depth of a few hundred nanometres to a few tens of micrometres,
so as to form a structure of comb-like material having rods and light entrapment cavities between said rods so as to absorb the light resulting in a black appearance.

FIG. 1 shows three diagrams, viewed from the side and from the top, illustrating examples of various phase size, phase fraction and phase spacing cylinders.

The crystalline phase 1 is in the form of filaments or fine dendrites aligned in a direction or axis Z.

For example, the crystalline phase represents between 3% and 50% by volume of the material. The other phase, referred to as the matrix 2, surrounds the filaments and represents the remainder of the alloy, in particular between 50% and 97% by volume of material.

The starting face 3 can be any material provided that directed growth is enabled.

When selecting the chemical elements of the material, an important criterion is the etching that will dissolve or remove at least part of the matrix and leave the filaments or fine dendrites of the crystalline phase exposed along a certain depth, for example from a few hundred nanometres to a few hundred microns depending on the size and spacing of the filaments or fine dendrites.

Preferably, the removal step is carried out chemically. The etching solution must be determined according to the chemistry of the alloy and the phases present, in order to dissolve the matrix without etching the filaments or fine dendrites too much. Therefore, the matrix must be etched using a product that does not etch the other phase (or only slightly).

For example, the removal step is chemically carried out using a solution comprising NaOH or HNO3, for example using a bath of said solution. In other words, the removal step is carried out using a solution comprising NaOH. Alternatively, the removal step is carried out using a solution comprising HNO3.

According to one example, using an Al—Ni eutectic alloy with 3.1% nickel as the material, an Al3Ni crystalline phase of approximately 12% is produced in a matrix of approximately 88% solid aluminium solution. The solid aluminium solution can be dissolved in a solution comprising NaOH, which will not etch the Al3Ni phase (or only very slightly). The solution can take several minutes or several hours to act.

According to another example, an etch of the Al—Zn alloy (59% Zn) in an HNO3 solution can be foreseen to dissolve the solid zinc solution and expose the solid aluminium solution dendrites. The solution can be diluted to varying degrees and can take a variable amount of time, for example, between several minutes and several hours. This Al—Zn alloy is non-eutectic.

With reference to FIGS. 3 and 4, the manufacturing method can further provide for a blanking step in a direction transverse to the rod extension direction, in particular in a direction perpendicular to the axis Z or substantially perpendicular to that axis Z.

The growth step aims to grow straight rods from the crystalline phase. In particular, the blanking step makes it possible to cut, along a plane substantially perpendicular to the main direction, the ends of the rods, Al3Ni in the example above, so as to obtain rod ends substantially perpendicular to the sectional plane, see FIG. 4, and therefore to the surface of the part to be blackened. In other words, the growth step is carried out by solidifying a eutectic Al—Ni alloy with 3.1% nickel Ni.

Preferably, the blanking step is carried out after the growth step and before the removal step.

The perpendicular surface thus created corresponds to the black surface after etching.

Optionally, a step of polishing and/or sandblasting the surface of the part can be provided for in order to improve the random appearance of the surface.

Thus, in one aspect of the invention, the method for manufacturing the black structure of a material such as an Al—Ni eutectic alloy with 3.1 at % Ni comprises at least two phases, including at least one crystalline phase and at least one other phase, referred to as the matrix. In this context, the method comprises the step in which the material is grown by directional solidification in a main direction Z such that the at least one crystalline phase forms a plurality of rods aligned with each other and the matrix extends between the rods. The method also comprises the step of removing, using a solution comprising NaOH, at least part of the matrix between the rods of the at least one crystalline phase, so as to form a comb-like material structure having rods and light entrapment cavities between said rods. It should be noted that this removal step can alternatively be carried out using a solution comprising HNO3.

Thus, in another aspect of the invention, the method of manufacturing the black structure of a material such as an Al—Zn alloy with 59 at % of Zn comprises at least two phases, including at least one crystalline phase and at least one other phase, referred to as the matrix. In this context, the method comprises the step in which the material is grown by directional solidification in a main direction Z such that the at least one crystalline phase forms a plurality of rods aligned with each other and the matrix extends between the rods. The method also comprises the step of removing, using a solution comprising HNO3, at least part of the matrix between the rods of the at least one crystalline phase, so as to form a comb-like material structure having rods and light entrapment cavities between said rods. It should be noted that this solution helps dissolve the solid zinc solution and expose the solid aluminium solution dendrites.

In another aspect, the invention relates to the use of the black structure obtained by this method for external horology parts. This use comprises manufacturing this black structure from a material such as an eutectic Al—Ni alloy with 3.1 at % Ni providing for at least two phases, including at least one crystalline phase and at least one other phase, referred to as the matrix. Alternatively, this material can be an Al—Zn alloy with 59 at % of Zn. In this context, in this manufacturing process, the material growth step is implemented by directional solidification in a main direction Z such that the at least one crystalline phase forms several rods aligned with each other and the matrix extends between the rods. During this manufacture, a solution comprising NaOH is also used in the step of removing at least part of the matrix between the rods of the at least one crystalline phase, so as to form a structure of comb-like material having rods and light entrapment cavities between said rods. It should be noted that this removal step can alternatively be carried out using a solution comprising HNO3.

1. A method for manufacturing a black structure of a material (10) comprising at least two phases, with at least one crystalline phase (1) and at least one other phase, referred to as the matrix (2), the method being characterised in that it comprises the following steps:
growing the material in a main direction (Z) so that the at least one crystalline phase forms a plurality of rods aligned with each other and the matrix extends between the rods; and
removing at least part of the matrix between the rods of the at least one crystalline phase, so as to form a comb-type material structure with rods and light entrapment cavities between said rods.

2. The method according to claim 1, wherein the material is metal, ceramic or polymer, or a combination thereof.

3. The method according to claim 1, wherein the material is an alloy, preferably aluminium-based and/or nickel-based and/or zinc-based.

4. The method according to claim 1, wherein the growth step is carried out by directional solidification.

5. The method according to claim 1, wherein the removal step is carried out chemically or electrochemically, thermally or physically.

6. The method according to claim 1, wherein the removal step is carried out using a solution comprising NaOH or HNO3, preferably in a bath of said solution.

7. The method according to claim 1, further comprising a blanking step in a transverse direction to the rod extension direction, between the growth step and the removal step.

8. The method according to claim 1, further comprising a polishing and/or a sandblasting step.

9. Use of a black structure produced by the method according to claim 1 for external horology parts.

10. An external horology part produced using the method according to claim 1.

11. The external horology part according to claim 10 wherein the horology part is a black part.

12. The external horology part according to claim 10, comprising a material comprising at least two phases including at least one crystalline phase and at least one other phase, referred to as the matrix.
